(19) United States
(12) Patent Application Publication
(10) Pub. No.: US 2009/0197210 A1
(43) Pub. Date: Aug. 6, 2009

(54) Method for preparing photonic crystal slab waveguides

(75) Inventors: Lon Wang, Taipei (TW); Ma Khine Zar Lin, Hsin-Chu (TW); Yung-Pin Chen, Taipei (TW)

Correspondence Address: BACON & THOMAS, PLLC, 625 SLATERS LANE, FOURTH FLOOR, ALEXANDRIA, VA, 22314-1176, US

(73) Assignee: National Taiwan University, Taipei (TW)

(21) Appl. No.: 12/318,674

(22) Filed: Jan. 6, 2009

(30) Foreign Application Priority Data
Jan. 31, 2008 (TW) 097103687

(51) Int. Cl. G03F 7/20

(52) U.S. Cl. 430/321

(57) ABSTRACT

A method for preparing a photonic crystal slab waveguides is disclosed, wherein the photonic crystal slab waveguides are prepared by combining near-field phase-shifting contact lithography (NFPSCL) with interference lithography (IL). Conventional methods used for preparing the photonic crystal slab waveguides, such as electron beam lithography or direct laser writing, are time consuming. In contrast, the present method allows rapid production of many photonic crystal slab waveguides over a large area composed of microstructures.

### BACKGROUND OF THE INVENTION

1. Field of the Invention

The present invention relates to a method for preparing photonic crystal slab waveguides and, more particularly, to a method for preparing photonic crystal slab waveguides for light transport.

2. Description of Related Art

Photonic crystals are composed of periodic dielectric structures, and the forms of the photonic crystals can be divided into 1-dimensional, 2-dimensional, and 3-dimensional structures. The photonic crystals can affect the light propagation through the periodic dielectric structures depending on the wavelength of the light. Besides, the photonic crystals are used in light transport, so the periodicity of photonic crystal structure has to be similar to the operating wavelength of light.

Currently, progress in the semiconductor processing has enabled the photonic crystals to be realized. In addition, the photonic crystals can be applied widely in the fields of optical communication and optical light sources due to their unique characteristics. The 2-dimensional photonic crystals have been employed in waveguide elements, beam splitters, and Mach-Zehnder interferometers. The techniques have been used for manufacturing 2-dimensional photonic crystals including lithography and etching techniques, which are usually used in conventionally semiconductor processing.

The 2-dimensional photonic crystal comprising the waveguide elements is called photonic crystal slab waveguides. The defect structures incorporated into the photonic crystal can confine and guide light along the defect structures. FIG. 1 shows conventional photonic crystal slab waveguides. Photonic crystals 112 are formed on the substrate 11, and the defect structures in the photonic crystals 112 are called waveguides 111. The loss of photons is extremely low during light transport in the photonic crystal slab waveguides. Particularly, light can transport in the waveguides with right angles (i.e. 90°). Hence, the photonic crystal slab waveguides are suitable for connecting micro opto-electronic elements in advanced integrated circuits (ICs).

Several fabrication methods for photonic crystal slab waveguide are being developed currently. For example, interference lithography (IL) is combined with electron beam lithography, focused ion beam (FIB), direct laser writing, and photolithography technique to fabricate photonic crystals containing defects. However, either electron beam or ion beam lithography for defining the waveguides in photonic crystals is very time consuming because of inherent writing speed of each is too slow especially when the waveguides are long. Furthermore, the waveguides can be defined rapidly in photonic crystals by the direct laser writing or the photolithography technique, but light diffraction may cause additional problems for waveguide patterning, limiting the line widths of waveguides. Hence, it is difficult for the aforementioned methods to fabricate the photonic crystal slab waveguide over a large area composed of photonic crystal micro structures.

Therefore, it is desirable to provide a simple method to fabricate photonic crystal slab waveguide having different periods and line widths rapidly and economically. It is also desirable to form photonic crystal slab waveguide with different photonic crystal pattern and waveguide pattern, which can be applied in various kinds of communication elements, sensor elements, and opto-electronic elements.

### SUMMARY OF THE INVENTION

The object of the present invention is to provide a method for preparing photonic crystal slab waveguides, which combines Near-Field Phase-Shifting Contact Lithography (NFPSCL) and Interference Lithography (IL), to fabricate photonic crystal slab waveguides over a large area rapidly.

To achieve the object, the method for preparing photonic crystal slab waveguides of the present invention includes the following steps: (A) providing a phase-shift mask on a base; (B) applying a light source over the phase-shift mask to form an etching mask having a waveguide pattern on a surface of the base, and removing the phase-shift mask; (C) applying at least two coherent light beams with predetermined configurations on the surface of the base to form an etching mask having a photonic crystal pattern on the surface of the base; and (D) etching the base to form a photonic crystal with at least one waveguide on the base, and removing the etching mask.

In the process for preparing waveguides, the waveguide pattern can be adjusted through the phase-shift mask of the present invention. Besides, through adjustment in exposure doses of the light source, the waveguides with different line widths can be prepared by the same phase-shift mask. Furthermore, using two coherent light beams multiple times can form interference fringes, wherein predetermined angles can be formed between the interference fringes to prepare photonic crystal with good periodicity. Plural coherent light beams with the same incident angle can also perform interference lithography by different azimuth angles at the same time to prepare photonic crystal with good period. Hence, it is possible to fabricate photonic crystal slab waveguides rapidly and economically by the method for preparing photonic crystal slab waveguides of the present invention.

In addition, in the method for preparing photonic crystal slab waveguides of the present invention, the base comprises: a substrate, an etch-mask layer covering on the substrate, and a photoresist layer covering on the etch-mask layer, wherein the etch-mask layer is disposed between the photoresist layer and the substrate. Besides, the material of the substrate is not limited. Preferably, the material of the substrate is Si, or silicon on insulator (SOI).

In one aspect of the present invention, the step (C) of the method for preparing photonic crystal slab waveguides may be a step (C1): projecting an interference pattern on the photoresist layer with two coherent light beams; rotating the base with a rotation angle; projecting another interference pattern on the photoresist layer to form the photonic crystal pattern; and forming the etching mask having the photonic crystal pattern on the surface of the base.

Furthermore, in another aspect of the present, the step (C) of the method for preparing photonic crystal slab waveguides may be a step (C2): projecting multiple interference patterns on the photoresist layer by using more than two coherent light beams with different azimuth angles at the same time to form the photonic crystal pattern, and forming the etching mask having the photonic crystal pattern on the surface of the base.

In the method for preparing photonic crystal slab waveguides of the present invention, the waveguide pattern, which is formed on the photoresist layer by the phase-shift mask, is transferred to the etch-mask layer by removing the etch-mask layer.

In the method for preparing photonic crystal slab waveguides of the present invention, the photonic crystal pattern on the photoresist layer is transferred to the etch-mask layer by removing the etch-mask layer.

Particularly, in the method for preparing photonic crystal slab waveguides of the present invention, step (C) for forming the photonic crystal pattern may be performed before the step (B) for forming the waveguide pattern.

In the method for preparing photonic crystal slab waveguides of the present invention, the light source is unlimited. Preferably, the light source is near-UV light.

Preferably, in the method for preparing photonic crystal slab waveguides of the present invention, the material used in the etching mask is Sn, Ag, Cu, Au, Cr, Ti, Zn, Ni, Cu—Cr alloy, or Zn—Pb alloy. More preferably, the material used in the etching mask is Cr.

In the method for preparing photonic crystal slab waveguides of the present invention, the material used in the phase-shift mask is a light-transmitting material, which may include a light-transmitting and rigid material, or a light-transmitting and elastomeric material. Preferably, the material used in the phase-shift mask is silicon dioxide (SiO₂), or polydimethylsiloxane (PDMS). Furthermore, the phase-shift mask may be a bulk having a relief pattern, and a relief depth on the surface of the bulk.

In the method for preparing photonic crystal slab waveguides of the present invention, the material used in the photoresist layer is unlimited. Preferably, the material used in the photoresist layer is positive photoresist.

In the method for preparing photonic crystal slab waveguides of the present invention, the line width of the waveguides may be 100 nm-1.3 μm. Besides, the line width of the waveguides may comprise one fold, or multiple folds of photonic crystal periods.

Moreover, in an aspect of the present invention, plural coherent light beams at different azimuth directions may generate 2-dimensional photonic crystals. Two of the plural coherent light beams with the same incident angle generate first interference fringes, wherein the difference in the azimuth angles of the two coherence light beams is 180°. Another two of the plural coherent light beams at specific azimuth directions generate second interference fringes, wherein predetermined angles between the first interference fringes and the second interference fringes are the same as the difference angles between the azimuth directions of the coherent light beams which generate the first interference fringes and the second interference fringes. Besides, third interference fringes can be generated by the same method for generating the first interference fringes and the second interference fringes, wherein the azimuth directions for generating the third interference fringes are different from the azimuth directions for generating the first interference fringes and the second interference fringes. Hence, by using multiple interferences with different azimuth angles, 2-dimensional photonic crystals with different patterns can be formed.

Preferably, the line widths of each of the first interference fringes, the second interference fringes, or the third interference fringes are the same. Besides, preferably, the gaps between the adjacent first interference fringes, the adjacent second interference fringes, and the adjacent third interference fringes are the same. Furthermore, if four coherent light beams generate the first interference fringes and the second interference fringes at the same time, the predetermined angles between the first interference fringes and the second interference fringes are about 90°, preferably. If six coherent light beams generate the first interference fringes, the second interference fringes, and the third interference fringes at the same time, the predetermined angles between the first interference fringes, the second interference fringes, and the third interference fringes are about 60°.

Other objects, advantages, and novel features of the invention will become more apparent from the following detailed description when taken in conjunction with the accompanying drawings.

### BRIEF DESCRIPTION OF THE DRAWINGS

FIG. 1 is a perspective view of a conventional photonic crystal slab waveguide;

FIG. 2A to FIG. 2E are cross-sectional views showing a process for preparing a phase-shift mask of the present invention;

FIG. 3A to FIG. 3F are cross-sectional views showing a process for preparing another phase-shift mask of the present invention;

FIG. 4A to FIG. 4H are cross-sectional views showing a process for preparing a photonic crystal of the embodiment 1 of the present invention;

FIG. 5 is a top view of a photonic crystal slab waveguides of the embodiment 1 of the present invention;

FIG. 6A to FIG. 6F are cross-sectional views showing a process for preparing a photonic crystal of the embodiment 2 of the present invention;

FIG. 7 is a top view of a photonic crystal of the embodiment 2 of the present invention; and

FIG. 8A to FIG. 8F are perspective views of showing a process for preparing a photonic crystal of the embodiment 3 of the present invention.

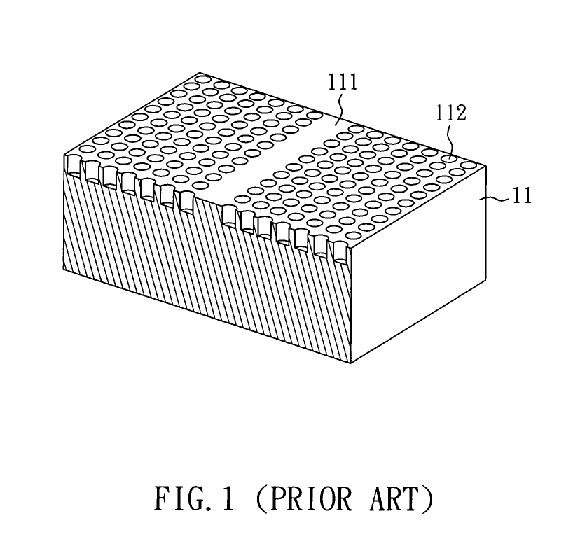

### DETAILED DESCRIPTION OF THE PREFERRED EMBODIMENT

### 1-1 A Method for Preparing a Phase-Shift Mask

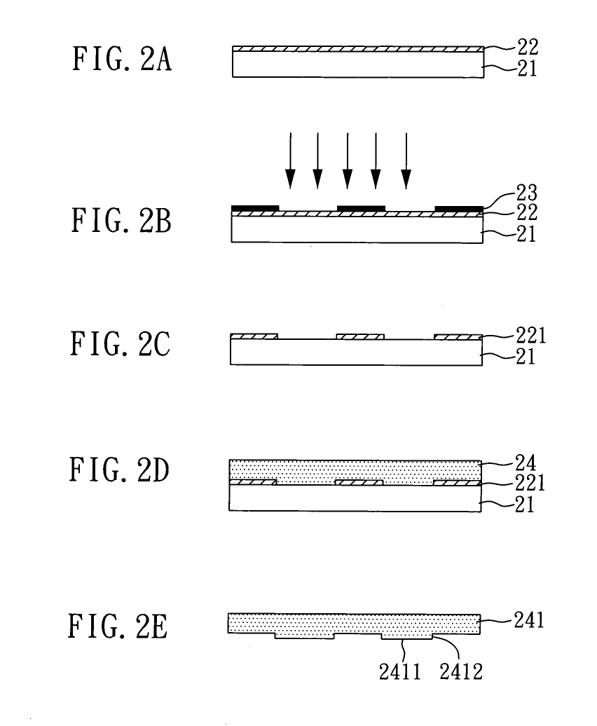

FIG. 2A to FIG. 2E are cross-sectional views showing a process for preparing a phase-shift mask of the present invention. First, with reference to FIG. 2A, a substrate 21 is provided, and then a photoresist film 22 is coated on the substrate 21. The general method for coating photoresist film 22 is dip coating, roll coating, printing, laminating, or spin coating. Here, the photoresist 22 is coated on the substrate 21 by spin coating. One kind of positive photoresist, which can be used for preparing a phase-shift, is EPG510. However, the ultimate thickness of the photoresist film 22 is 700 nm with 6000 rpm spinning speed, due to the viscosity of EPG510. Hence, the material used for forming the photoresist film 22 is a positive photoresist comprising EPG510 and EPT10, wherein the weight ratio between EPG510 and EPT10 is 5:1. The thickness of the photoresist film 22, which is prepared with the mix of EPG510 and EPT10, is 500 nm by the spinning speed 6000 rpm.

With reference to FIG. 2B, a mask 23 is placed in contact with the photoresist film 22. Then, the photoresist film 22 is patterned by conventional photolithography. After removing the mask 23, the photoresist film 22 is treated with a post-exposure-bake (PEB) to harden the photoresist film 22 and make the pattern formed on the photoresist film 22 clearer. After development processing, a photoresist pattern 221 is formed, as shown in FIG. 2C.

With reference to FIG. 2D, a prepolymer of PDMS is cast on the photoresist pattern 221. After curing the PDMS, the photoresist pattern 221 is transferred to a polymer of PDMS. As shown in FIG. 2E, an elastomeric phase-shift mask 221 is formed.

The PDMS used for the phase-shift mask is a light-transmitting and elastomeric material.

### 1-2 A Method for Preparing a Phase-Shift Mask

Here, another method for preparing a phase-shift mask is provided, wherein the material used for the phase-shift mask of the present invention can further be a light-transmitting and rigid material.

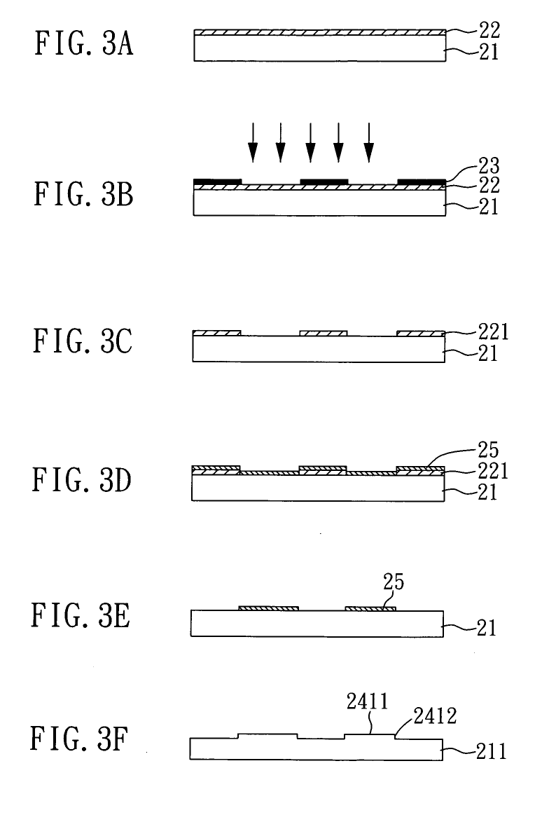

With reference to FIG. 3A, a substrate 21 is provided, and then a photoresist film 22 is coated on the substrate 21. The material of the substrate 21 can be any kind of light-transmitting materials, such as glass or quartz. The material of the substrate 21 used herein is glass. With reference to FIG. 3B, a mask 23 is placed in contact with the photoresist film 22. Then, the photoresist film 22 is patterned by conventional photolithography. After removing the mask 23, the photoresist film 22 is treated with PEB to harden the photoresist film 22 and make the pattern formed on the photoresist film 22 clearer. After development processing, a photoresist pattern 221 is formed, as shown in FIG. 3C.

With reference to FIG. 3D, after the photoresist pattern 221 is obtained, a metal mask 25 can be plated on the photoresist pattern 221 directly, due to the material of the substrate is a light-transmitting material. After removing the photoresist pattern 221 (as shown in FIG. 3E), the substrate 21 is etched by anisotropic etching. With reference to FIG. 3F, a rigid phase-shift mask is formed after removing the metal mask 25.

### Embodiment 1

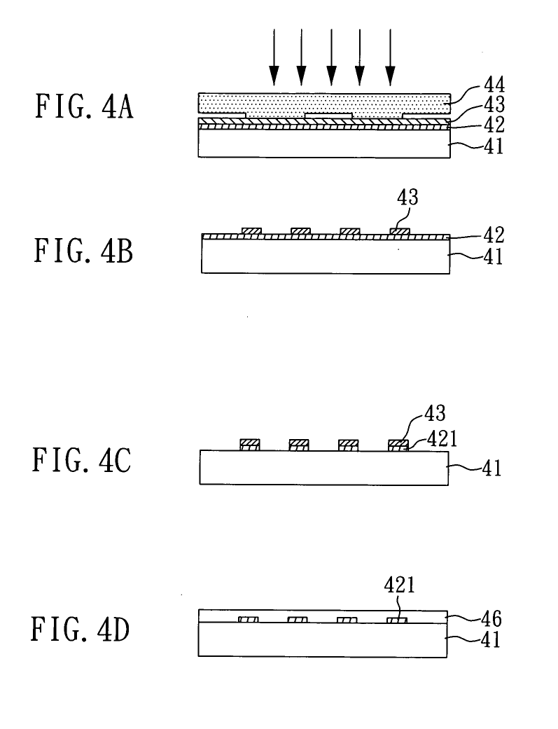

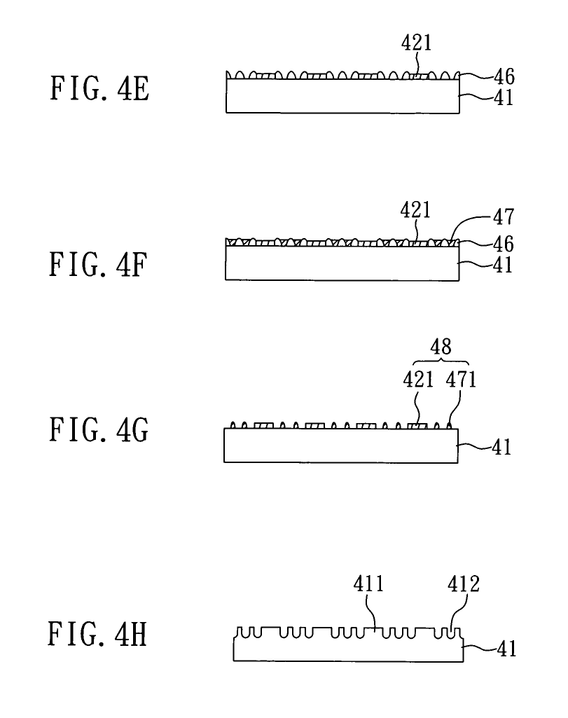

The method for preparing photonic crystal slab waveguides of the present embodiment is described with reference to FIG. 4A to FIG. 4H, wherein FIG. 4A to FIG. 4H are cross-sectional views showing a process for preparing a photonic crystal slab waveguides of the present embodiment.

The method for preparing photonic crystal slab waveguides of the present embodiment comprises the following steps:

First, with reference to FIG. 4A, a substrate 41 is provided, wherein the material of the substrate 41 may be Si or SOI. In the present embodiment, the material of the substrate 41 is SOI.

A first metal layer 42 is deposited on the substrate 41 by e-gun evaporation (as shown in FIG. 4A), wherein the material of the first metal layer 42 may be Sn, Ag, Cu, Au, Cr, Ti, Zn, Ni, Cu—Cr alloy, Sn—Pb alloy. In the present embodiment, the material of the first metal layer 42 is Cr.

Then, a first photoresist layer 43 is coated on the first metal layer 42 by spinning coating, and the first metal layer 42 is disposed between the substrate 41 and the first photoresist layer 43 (as shown in FIG. 4A). In the present embodiment, the material of the first photoresist layer 43 is a positive photoresist.

A phase-shift mask 44 is provided and placed on the first photoresist layer 43, so that the first photoresist layer 43 is disposed between the phase-shift mask 44 and the first metal layer 42 (as shown in FIG. 4A). In the present embodiment, the material used for the phase-shift mask 44 is PDMS.

A light source is applied over the phase-shift mask 44 to expose and pattern the first photoresist layer 43 (as shown in FIG. 4B). In the present embodiment, the light source is UV radiation.

After removing the phase-shift mask and etching the first metal layer 42, the pattern (not shown in the figure) is transferred to the first metal layer 42, and a waveguide pattern 421 is formed in the first metal layer 42 (as shown in FIG. 4C).

After forming the waveguide pattern 421, the first photoresist layer 43 is removed. Then a second photoresist layer 46 is coated on the first metal layer 42 having the waveguide pattern 421 by spinning coating (as shown in FIG. 4D).

In the present embodiment, Ar⁺ laser is used for IL. Plural first interference fringes (not shown in the figure) are formed on the second photoresist layer 46 by coherent light beams. Furthermore, in the present embodiment, the line widths of each first interference fringes are the same, and the gaps between the adjacent first interference fringes are the same.

Plural second interference fringes (not shown in the figure) are formed on the second photoresist layer 46 by Ar⁺ laser to pattern the second photoresist layer 46, wherein predetermined angles are formed between the first interference fringes and the second interference fringes (as shown in FIG. 4E). Besides, in the present embodiment, the line widths of each second interference fringes are the same, and the gaps between the adjacent second interference fringes are the same. Furthermore, the predetermined angles between the first interference fringes and the second interference fringes are about 90°.

Plural third interference fringes (not shown in the figure) may be formed on the second photoresist layer 46 by performing IL for the third time to pattern the second photoresist layer 46, wherein other predetermined angles are formed between the first interference fringes, the second interference fringes, and the third interference fringes. In the present embodiment, the line widths of each third interference fringes are the same, and the gaps between the adjacent third interference fringes are the same. Besides, the predetermined angles between the first interference fringes, the second interference fringes, and the third interference fringes are about 60°.

Plural coherent light beams with the same incident angle may also perform interference lithography by different azimuth angles at the same time to form interference fringes on the second photoresist layer 46, and to pattern the second photoresist layer 46.

Four beams may be used at the same time to form the first interference fringes and the second interference fringes on the second photoresist layer 46, wherein predetermined angles are formed between the first interference fringes and the second interference fringes. In the present embodiment, the line widths of each first interference fringes are the same, and the gaps between the adjacent first interference fringes are the same. Besides, the line widths of each second interference fringes are the same, and the gaps between the adjacent second interference fringes are the same. Preferably, the predetermined angles between the first interference fringes and the second interference fringes are about 90°.

Six beams may be used at the same time to form the first interference fringes, the second interference fringes, and the third interference fringes on the second photoresist layer 46, wherein predetermined angles are formed between the first interference fringes, the second interference fringes, and the third interference fringes. In the present embodiment, the line widths of each first interference fringes are the same, and the gaps between the adjacent first interference fringes are the same. The line widths of each second interference fringes are the same, and the gaps between the adjacent second interference fringes are the same. Besides, the line widths of each third interference fringes are the same, and the gaps between the adjacent third interference fringes are the same. Preferably, the predetermined angles between the first interference fringes, the second interference fringes, and the third interference fringes are about 60°.

With reference to FIG. 4F, a second metal layer 47 is deposited on the second photoresist layer 46. Preferably, the material of the second metal layer 47 is the same as the material of the first metal layer 42. In the present embodiment, the material used in the second metal layer 47 is Cr.

After the second photoresist layer 46 is washed away by using acetone, the pattern on the second photoresist layer 46 is transferred to the substrate 41 to form a photonic crystal pattern 471 (as shown in FIG. 4F). The waveguide pattern 421 and the photonic crystal pattern 471 serve together as an etching mask 48 to etch the substrate 41 (as shown in FIG. 4G).

After the etching mask 48 is removed, a photonic crystal 412 with waveguides 411 is formed on the substrate, as shown in FIG. 4H.

In the present embodiment, after applying a light source over the phase-shift mask 44 to expose and pattern the first photoresist layer 43, the method for preparing photonic crystal slab waveguides may further comprise a step: treating the first photoresist layer 43 with PEB to make the pattern formed on the photoresist layer 43 clear. Besides, in the present embodiment, after the second photoresist layer 46 is patterned, the method for preparing photonic crystal slab waveguides may further comprise a step: treating the second photoresist layer 46 with PEB to make the pattern formed on the photoresist layer 46 clear.

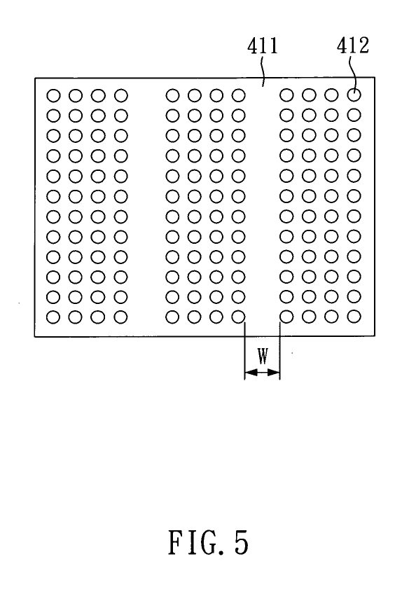

FIG. 5 is a top view of a photonic crystal slab waveguides of the present embodiment, wherein the photonic crystal slab waveguides comprises waveguides 411 and photonic crystals 412. Generally, the line widths W of the waveguides may be 100 nm-1.3 μm. In the present embodiment, the line widths W of the waveguides 411 are between 350 nm to 400 nm.

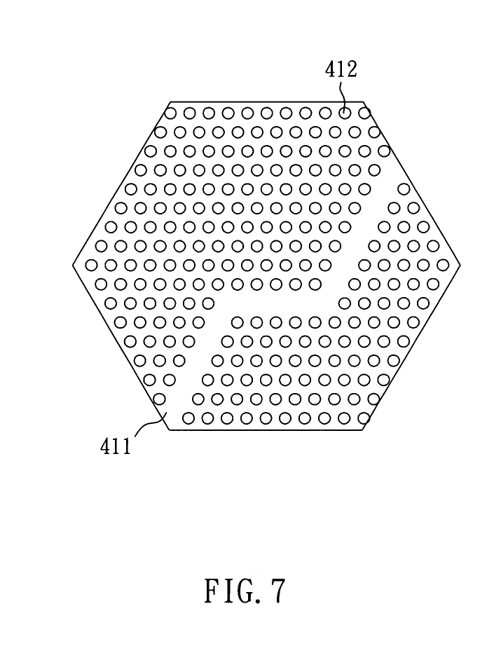

On the other hand, with reference to FIG. 5, FIG. 7, and FIG. 2E, the number and the pattern of the waveguides 421 of the photonic crystal slab waveguides are defined by the bottom edges 2411 of the phase-shift mask 241. The photonic crystal slab waveguides prepared in the present embodiment have 2 parallel waveguides 411. Besides, the line widths W of the waveguides 411 are defined according to the relief depths 2412 of the phase-shift mask 241 and the exposure dose of the light source. Table 1 presents the relationship between the relief depths 2412 of the phase-shift mask 241, the exposure dose of the light source, and the line widths W of the waveguides 411.

TABLE 1

| Exposure dose of light | Relief depth of | Line width of |
|---|---|---|
| source (mJ/cm²) | phase-shift mask (nm) | waveguides W (nm) |
| 25 | 500 | 150~400 |
| 25 | 700 | 400~600 |
| 25 | 1100 | 700~1100 |
| 15 | 500 | 120~200 |
| 15 | 700 | 200 |
| 15 | 1100 | 300~400 |

With reference to Table 1, FIG. 5, FIG. 7, and FIG. 2E, different line widths W of the waveguides 411 can be prepared with different relief depths of the phase-shift mask 241 at the same exposure dose of the light source. Furthermore, different line widths W of the waveguides 411 can be prepared with the same relief depths of the phase-shift mask 241 by adjusting the exposure dose of the light source. Hence, the line widths W of the waveguides 411 can be defined by the exposure dose of the light source and the relief depths 2412 of the phase-shift mask 241.

### Embodiment 2

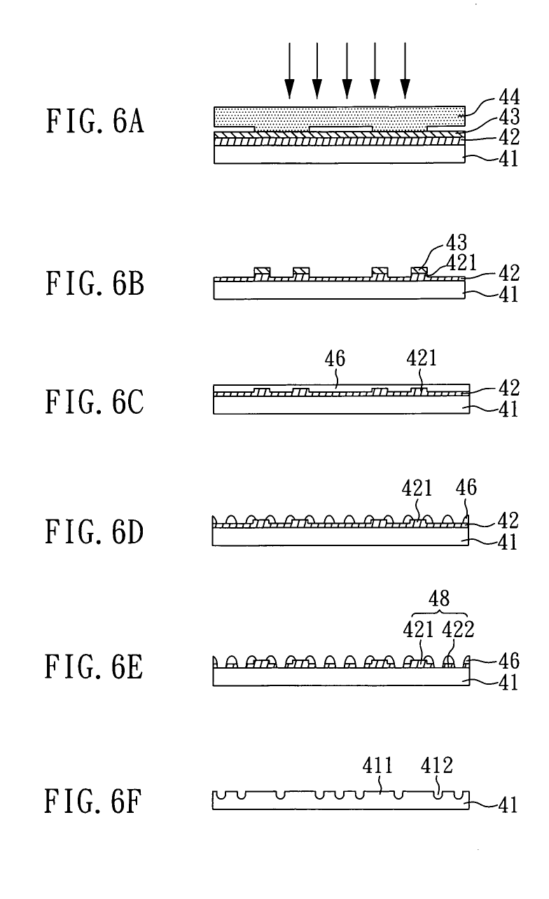

FIG. 6A to FIG. 6H are cross-sectional views showing a process for preparing a photonic crystal of the present embodiment.

First, with reference to FIG. 6A, a substrate 41 is provided. Then, a first metal layer 42, and a first photoresist layer 43 are disposed on the substrate 41. The first photoresist layer 43 is exposed and patterned by way of a phase-shift mask 44.

After removing the phase-shift mask 44, the first metal layer 42 is etched to form a waveguide pattern 421, as shown in FIG. 6B.

With reference to FIG. 6C, a second photoresist layer 46 is coated on the first metal layer 42 after the first photoresist layer 43 is removed.

With reference to FIG. 6D, plural first interference fringes are projected on the second photoresist layer 46 by coherent light beams. In the present embodiment, the line widths of each first interference fringes are the same, and the gaps between the adjacent first interference fringes are the same. Then, plural second interference fringes are projected on the second photoresist layer 46, wherein the first interference fringes and the second interference fringes cross each other. In the present embodiment, the line widths of each second interference fringes are the same, and the gaps between the adjacent second interference fringes are the same. Finally, plural third interference fringes are projected on the second photoresist layer 46, wherein predetermined angles are formed between the first interference fringes, the second interference fringes, and the third interference fringes. In the present embodiment, the line widths of each third interference fringes are the same, and the gaps between the adjacent third interference fringes are the same. Besides, the predetermined angles are about 60°.

With reference to FIG. 6D and FIG. 6E, the second photoresist layer 46 serves as a mask to etch the first metal layer 42 to form a photonic crystal pattern 422. After removing the second photoresist layer 46, the waveguide pattern 421 and the photonic crystal pattern 422 serve together as an etching mask 48 to etch the substrate 41. Finally, after the etching mask 48 is removed, a photonic crystal 412 with waveguides 411 is formed on the substrate 41, as shown in FIG. 6F.

With reference to FIG. 7, the photonic crystal 412 is formed by processing IL three times in the present embodiment. Besides, the patterns of the waveguides 411 are defined by the bottom edges 2411 of the phase-shift mask 241 (with reference to FIG. 2E).

### Embodiment 3

In methods for preparing photonic crystal slab waveguides disclosed in the embodiment 1 and embodiment 2, a photonic crystal pattern is formed after a waveguide pattern. However, in the present embodiment, the waveguide pattern is formed after the photonic crystal pattern.

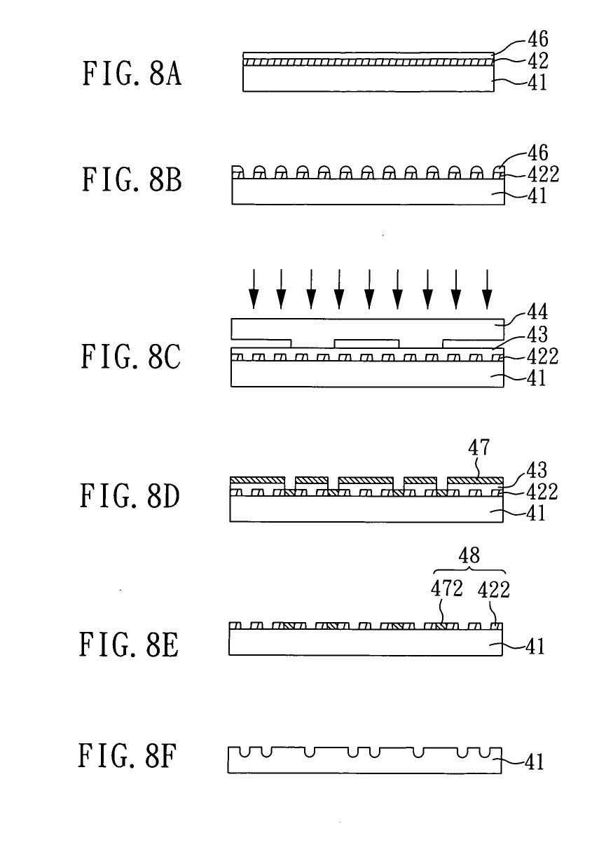

FIG. 8A to FIG. 8C are cross-sectional views showing a process for preparing a photonic crystal of the present embodiment.

With reference to FIG. 8A, a first metal layer 42 and a second photoresist layer 46 are formed on the substrate 41 sequentially. Then, plural first interference fringes and plural second interference fringes are projected on the second photoresist layer 46 sequentially to pattern the second photoresist layer 46. Besides, the angles formed between the first interference fringes and the second interference fringes are 90°.

Plural third interference fringes may be formed on the second photoresist layer 46 by performing IL for the third time to pattern the second photoresist layer 46, wherein other predetermined angles are formed between the first interference fringes, the second interference fringes, and the third interference fringes. In the present embodiment, the line widths of each third interference fringes are the same, and the gaps between the adjacent third interference fringes are the same. Besides, the predetermined angles between the first interference fringes, the second interference fringes, and the third interference fringes are about 60°.

Plural coherent light beams with the same incident angle may also perform interference lithography by different azimuth angles at the same time to form interference fringes on the second photoresist layer 46, and to pattern the second photoresist layer 46.

Four beams may be used at the same time to form the first interference fringes and the second interference fringes on the second photoresist layer 46, wherein predetermined angles are formed between the first interference fringes and the second interference fringes. In the present embodiment, the line widths of each first interference fringes are the same, and the gaps between the adjacent first interference fringes are the same. Besides, the line widths of each second interference fringes are the same, and the gaps between the adjacent second interference fringes are the same. Preferably, the predetermined angles between the first interference fringes and the second interference fringes are about 90°.

Six beams may be used at the same time to form the first interference fringes, the second interference fringes, and the third interference fringes on the second photoresist layer 46, wherein predetermined angles are formed between the first interference fringes, the second interference fringes, and the third interference fringes. In the present embodiment, the line widths of each first interference fringes are the same, and the gaps between the adjacent first interference fringes are the same. The line widths of each second interference fringes are the same, and the gaps between the adjacent second interference fringes are the same. Besides, the line widths of each third interference fringes are the same, and the gaps between the adjacent third interference fringes are the same. Preferably, the predetermined angles between the first interference fringes, the second interference fringes, and the third interference fringes are about 60°.

With reference to FIG. 8B, the second photoresist layer 46 serves as a mask to etch the first metal layer 42 to form a photonic crystal pattern 422.

After the second photoresist layer 46 is removed, a first photoresist layer 43 is coated on the photonic crystal pattern 422, as shown in FIG. 8C. Then, a phase-shift mask is provided on the first photoresist layer 43.

A UV radiation is applied over the phase-shift mask 44 to pattern the first photoresist layer 43. After the phase-shift mask 44 is removed, a second metal layer 47 is formed on the first photoresist layer 43 by e-gun evaporation (as shown in FIG. 8D). Preferably, the material used in the second metal layer 47 is the same as the material used in the material used in the first metal layer 42. In the present embodiment, the material used in the second metal layer 47 is Cr. When the first photoresist layer 43 is removed, the second metal layer 47 is also removed at the same time. Hence, with reference to FIG. 8E, only the waveguide pattern 472 is kept on the substrate 41.

Finally, the waveguide pattern 472 and the photonic crystal pattern 422 are served together as an etching mask 48 to etch the substrate 41. After removing the etching mask 48, the photonic crystal slab waveguides is achieved, as shown in FIG. 8F.

In conclusion, in the present invention, waveguides having different line widths can be easily achieved with only one phase-shift mask by controlling the exposure dose of the light source and the relief depths of the phase-shift mask. Hence, the cost for manufacturing can be reduced. In addition, the 2-dimensional interference fringes can be fabricated at the same time or at multiple times, so it is possible to prepare photonic crystal with good period quickly. Hence, it is possible to prepare photonic crystal slab waveguides over a large area by the method for preparing photonic crystal slab waveguides of the present invention.

Although the present invention has been explained in relation to its preferred embodiment, it is to be understood that many other possible modifications and variations can be made without departing from the scope of the invention as hereinafter claimed.

What is claimed is:

1. A method for preparing photonic crystal slab waveguides, comprising:
(A) providing a phase-shift mask on a base;
(B) applying a light source over the phase-shift mask to form an etching mask having a waveguide pattern on a surface of the base, and removing the phase-shift mask;
(C) applying at least two coherent light beams with predetermined configurations on the surface of the base to form an etching mask having a photonic crystal pattern on the surface of the base; and
(D) etching the base to form a photonic crystal with at least one waveguide on the base, and removing the etching mask.

2. The method for preparing photonic crystal slab waveguides as claimed in claim 1, wherein the phase-shift mask is a bulk having a relief pattern, and a relief depth on a surface of the bulk.

3. The method for preparing photonic crystal slab waveguides as claimed in claim 2, wherein the material used in the phase-shift mask is a light-transmitting and rigid material, or a light-transmitting and elastomeric material.

4. The method for preparing photonic crystal slab waveguides as claimed in claim 1, wherein the base comprises: a substrate, an etch-mask layer covering on the substrate, and a photoresist layer covering on the etch-mask layer, wherein the etch-mask layer is disposed between the photoresist layer and the substrate.

5. The method for preparing photonic crystal slab waveguides as claimed in claim 4, wherein the waveguide pattern, which is formed on the photoresist layer by the phase-shift mask, is transferred to the etch-mask layer by removing the etch-mask layer.

6. The method for preparing photonic crystal slab waveguides as claimed in claim 4, wherein the step (C) is a step (C1): projecting an interference pattern on the photoresist layer with two coherent light beams; rotating the base with a rotation angle; projecting another interference pattern on the photoresist layer to form the photonic crystal pattern; and forming the etching mask having the photonic crystal pattern on the surface of the base.

7. The method for preparing photonic crystal slab waveguides as claimed in claim 4, wherein the step (C) is a step (C2): projecting multiple interference patterns on the photoresist layer by using more than two coherent light beams with different azimuth angles at the same time to form the photonic crystal pattern, and forming the etching mask having the photonic crystal pattern on the surface of the base.

8. The method for preparing photonic crystal slab waveguides as claimed in claim 4, wherein the photonic crystal pattern on the photoresist layer is transferred to the etch-mask layer by removing the etch-mask layer.

9. The method for preparing photonic crystal slab waveguides as claimed in claim 1, wherein step (C) for forming the photonic crystal pattern is performed before the step (B) for forming the waveguide pattern.

10. The method for preparing photonic crystal slab waveguides as claimed in claim 1, wherein the line width of the at least one waveguide comprises one fold, or multiple folds of photonic crystal periods.
